(19) United States
(12) Patent Application Publication
(10) Pub. No.: US 2026/0271638 A1
(43) Pub. Date: Sep. 10, 2026

(54) SILICON INSULATION FILM FORMING METHOD

(71) Applicant: JUSUNG ENGINEERING CO., LTD., Gwangju-si, Gyeonggi-do (KR)

(72) Inventors: Jin Ho LEE, Gwangju-Si, Gyeonggi-do (KR); Jung Min KWON, Gwangju-Si, Gyeonggi-do (KR); Yoon Jeong KIM, Gwangju-Si, Gyeonggi-do (KR); Chul Joo HWANG, Gwangju-Si, Gyeonggi-do (KR)

(21) Appl. No.: 19/167,443

(22) PCT Filed: Mar. 21, 2024
(86) PCT No.: PCT/KR2024/095622

§ 371 Date: Sep. 22, 2025

(30) Foreign Application Priority Data
Mar. 23, 2023 (KR) 10-2023-0038043
Mar. 20, 2024 (KR) 10-2024-0038167

(51) Int. Cl. H10P 14/69; H01J 37/32; H10P 14/60; H10P 32/20

(52) U.S. Cl. CPC H10P 14/6903; H01J 37/32449; H10P 14/6339; H10P 14/6519; H10P 32/20; H01J 2237/3321; H01J 2237/338

(57) ABSTRACT

Presented is a method for forming a silicon insulating layer, and more particularly, to a method for forming a silicon insulating layer that is doped with oxygen on a substrate. A method for forming a silicon insulating layer according to an exemplary embodiment may be a method for forming a silicon insulating layer that is doped with oxygen and include preparing a substrate in a reaction space, forming a silicon insulating layer on the substrate through an atomic layer deposition process, and generating plasma in the reaction space by using a gas containing oxygen to dope oxygen into the silicon insulating layer.

### TECHNICAL FIELD

The present disclosure relates to a method for forming a silicon insulating layer, and more particularly, to a method for forming a silicon insulating layer that is doped with oxygen on a substrate.

### BACKGROUND ART

As a technology of depositing a thin film on a substrate, an atomic layer deposition (ALD) method is known, which deposits a thin film to a desired thickness by repeating a process of depositing the thin film in units of atomic layers. The atomic layer deposition method may deposit a thin film having excellent step coverage and high film density compared to the typical chemical vapor deposition (CVD) method.

The oxygen-doped silicon insulating layer is a dielectric widely used in manufacture of semiconductor devices and is mainly used as an interlayer dielectric (ILD) of a transistors such as a spacer for a gate electrode.

When such a silicon insulating layer is deposited using the atomic layer deposition method, hydrogen contained in a source gas containing silicon is inevitably contained in the silicon insulating layer. That is, the silicon insulating layer formed by the atomic layer deposition method has excellent step coverage and high thin film density, while the hydrogen content is relatively high compared to thin films formed by other deposition methods. Thus, in the related art, after forming the silicon insulating layer having the desired thickness on the substrate, a treatment process for removing hydrogen contained in the silicon insulating layer has been performed. However, in this case, there is a limitation in that it is difficult to effectively remove the hydrogen contained in the thin film because an area from which the hydrogen is removed is limited to a surface of the thin film.

### RELATED ART DOCUMENT

[Patent document] (Patent Document 1) KR 10-2013-0118963 A

### DISCLOSURE OF THE INVENTION

### Technical Problem

The present disclosure provides a method for forming a silicon insulating layer capable of forming an oxygen-doped silicon insulating layer while controlling a hydrogen content.

### Technical Solution

In accordance with an exemplary embodiment, a method for forming a silicon insulating layer that is doped with oxygen includes: preparing a substrate in a reaction space; forming a silicon insulating layer on the substrate through an atomic layer deposition process; and generating plasma in the reaction space by using a gas containing oxygen to dope oxygen into the silicon insulating layer.

At least one of the forming of the silicon insulating layer or the generating of the plasma may be performed multiple times.

After the generating of the plasma, the forming of the silicon insulating layer may be performed.

The generating of the plasma may include supplying a gas, in which one or more of nitrous oxide (N₂O), ozone (O₃), water (H₂O), ammonia (NH₃), nitrogen (N₂), oxygen (O₂), and argon (Ar) are combined, into the reaction space.

The forming of the silicon insulating layer may include: supplying a source gas containing trisilylamine (TSA); and supplying a reactant gas containing nitrogen.

The generating of the plasma may include: blocking a storage space for storing a gas containing oxygen from the reaction space; filling the storage space with the gas containing oxygen; and allowing the storage space to communicate with the reaction space so as to supply the gas containing oxygen to the reaction space.

In the supplying of the gas containing oxygen, a supply line that connects the storage space to the reaction space may be maximally opened at once to supply the gas containing oxygen.

The substrate or the reaction space may be maintained at a temperature of 100° C. to 400° C.

In accordance with another exemplary embodiment, a method for forming a silicon insulating layer that is doped with oxygen includes: preparing a substrate in a reaction space; supplying a gas containing silicon and a gas containing nitrogen onto the substrate to form a silicon insulating layer on the substrate through an atomic layer deposition process; and generating plasma in the reaction space by using a gas containing oxygen to dope oxygen into the silicon insulating layer.

At least one of the forming of the silicon insulating layer or the generating of the plasma may be performed multiple times.

After the generating of the plasma, the forming of the silicon insulating layer may be performed.

The generating of the plasma may include supplying a gas, in which one or more of nitrous oxide (N₂O), ozone (O₃), water (H₂O), ammonia (NH₃), nitrogen (N₂), oxygen (O₂), and argon (Ar) are combined, into the reaction space.

The gas containing silicon may include trisilylamine (TSA).

The generating of the plasma may include: blocking a storage space for storing a gas containing oxygen from the reaction space; filling the storage space with the gas containing oxygen; and allowing the storage space to communicate with the reaction space so as to supply the gas containing oxygen to the reaction space.

In the supplying of the gas containing oxygen, a supply line that connects the storage space to the reaction space may be maximally opened at once to supply the gas containing oxygen.

The substrate or the reaction space may be maintained at a temperature of 100° C. to 400° C.

### Advantageous Effects

According to the exemplary embodiment, the silicon insulating layer may be exposed to the plasma generated by using the gas containing the oxygen to perform the plasma treatment, thereby doping the oxygen on the silicon insulating layer and removing the hydrogen contained in the silicon insulating layer in the unit of the atomic layer.

In addition, the plasma treatment may be selectively performed to effectively control the hydrogen content within the oxygen-doped silicon insulating layer and also effectively control the components of the silicon insulating layer, which are changed in accordance with the plasma treatment.

### BRIEF DESCRIPTION OF THE DRAWINGS

FIG. 1 is a schematic view of an apparatus for processing a substrate in accordance with an exemplary embodiment;

FIG. 2 is a schematic view illustrating a method for forming a silicon insulating layer in accordance with an exemplary embodiment; and

FIG. 3 is a schematic view illustrating a method for forming a silicon insulating layer in accordance with another exemplary embodiment.

### MODE FOR CARRYING OUT THE INVENTION

Hereinafter, exemplary embodiments will be described in detail with reference to the accompanying drawings. The present invention may, however, be embodied in different forms and should not be construed as limited to the exemplary embodiments set forth herein. Rather, these embodiments are provided so that the present invention will be thorough and complete, and will fully convey the scope of the present invention to those skilled in the art.

It will also be understood that when a layer, a film, a region, or a substrate is referred to as being ‘on’ another one, it can be directly on the other one, or one or more intervening layers, films, regions, or substrates may also be present.

Also, spatially relative terms, such as “above” or “upper” and “below” or “lower” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. In the figures, the dimensions of layers and areas may be exaggerated for clarity of illustration. Like reference numerals refer to like elements throughout.

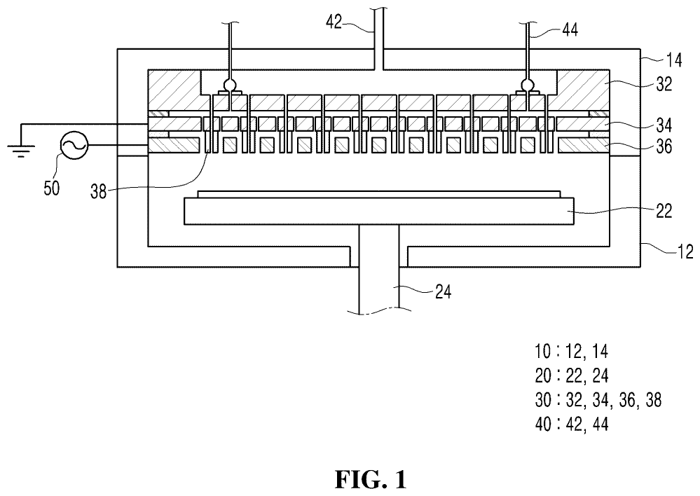

FIG. 1 is a schematic view of a apparatus for processing a substrate in accordance with an exemplary embodiment.

Referring to FIG. 1, an apparatus for processing a substrate in accordance with an exemplary may be an apparatus for forming a thin film, for example a silicon insulating layer, and may include a chamber 10, a substrate support part 20 prepared in the chamber 10 to support a substrate provided in the chamber 10, a gas injection part 30 prepared in the chamber 10 to face the substrate support part 20 and configured to inject a process gas toward the substrate support part 20, and a gas supply part 40 configured to supply a gas to the gas injection part 30. In addition, the apparatus for processing the substrate may further include an RF power source 50 applying power to generate plasma in the chamber 10 and a controller (not shown) controlling the RF power source 50. Here, the gas injection part 30 may be configured so that a first gas supply path for supplying a first gas and a second gas supply path for supplying a second gas are separated from each other.

The chamber 10 provides a predetermined reaction space and is maintained to seal the reaction space. The chamber 10 may include a body 12 including an approximately circular or square-shaped planar part and a sidewall extending upward from the planar part and having a predetermined reaction space and a lid 14 having an approximately circular or square shape and disposed on the body 12 to seal the reaction space. However, the chamber 10 is not limited thereto and may be manufactured in various shapes corresponding to the shape of the substrate.

An exhaust port (not shown) may be provided on a predetermined area of a bottom surface of the chamber 10, and an exhaust tube (not shown) connected to the exhaust port may be provided outside the chamber 10. Also, the exhaust tube may be connected to an exhaust device (not shown). A vacuum pump such as a turbo molecular pump may be used as the exhaust device. Therefore, the inside of the chamber may be vacuumized under a predetermined reduced pressure atmosphere, for example, to a predetermined pressure of 0.1 mTorr or less by the exhaust device. The exhaust tube may be installed not only on the bottom surface of the chamber 10, but also on a side surface of the chamber 10 under the substrate support part 20 to be described later. In addition, a plurality of exhaust tubes and the exhaust device corresponding thereto may be further installed to reduce an exhaust time.

The substrate provided into the chamber 10, in which the substrate processing process is performed, may be seated on the substrate support part 20. Here, the substrate may include a silicon wafer or glass and may include a substrate on which a separate thin film is already formed on the silicon wafer or glass. The substrate support part 20 may include an electrostatic chuck to adsorb and maintain the substrate S by using electrostatic force so that the substrate S is seated and supported. Alternatively, the substrate support part 20 may support the substrate S through vacuum adsorption or mechanical force.

The substrate support part 20 may be provided in a shape corresponding to a shape of the substrate, for example, a circular shape or a rectangular shape. The substrate support part 20 may include a substrate support 22 on which the substrate is seated and an elevator 24 disposed under the substrate support 22 to elevate the substrate support 22. Here, the substrate support 22 may be manufactured to be larger than the substrate, and the elevator 24 may be provided to support at least one area of the substrate support 22, for example, a central portion. When the substrate is seated on the substrate support 22, the substrate support 22 may move to approach the gas injection part 30. Also, a heater (not shown) may be installed in the substrate support 22. The heater generates heat to a predetermined temperature to heat the substrate support 22 and the substrate seated on the substrate support 22 so that the thin film is uniformly deposited on the substrate.

At least a portion of the gas supply part 40 may be installed outside the chamber 10 to supply a gas to the gas injection part 30. The gas supply part 40 may include a first gas supplier 42 and a second gas supplier 44. The first gas supplier 42 and the second gas supplier 44 may be connected to various types of gas reservoirs (not shown) to supply a gas required for the process to the reaction space through the gas injection part 30 and may be constituted by pipes that connect the gas reservoir to the gas injection part 30 to transfer the gas provided from the gas reservoir to the gas injection part 30.

For example, the source gas may be supplied to the reaction space through the first gas supplier 42, and a reactant gas may be supplied to the reaction space through the second gas supplier 44. However, the exemplary embodiment is not limited thereto, and on the contrary, the source gas may be supplied to the reaction space through the first gas supplier 42, and the reactant gas may be supplied to the reaction space through the second gas supplier 44. In addition, at least one of the first gas supplier 42 and the second gas supplier 44 may supply a gas for plasma-treating the substrate. For example, the plasma treatment gas may be supplied to the reaction space through the second gas supplier 44, but is not limited thereto. The plasma treatment gas may be supplied to the reaction space through the first gas supplier 42, or the plasma treatment gas may be supplied to the reaction space through the first gas supplier 42 and the second gas supplier 44. In addition, at least one of the first gas supplier 42 and the second gas supplier 44 may supply an inert gas such as an argon (Ar) gas or a low-reactivity gas such as a nitrogen (N₂) gas. Here, each of the first gas supplier 42 and the second gas supplier 44 may not necessarily provide one gas. For example, each of the first gas supplier 42 and the second gas supplier 44 may be configured to supply a plurality of gases at the same time or supply a gas selected from the plurality of gases.

The gas injection part 30 may be installed inside the chamber 10, for example, on a bottom surface of the lid 14, and a first gas supply path connected to the first gas supplier 42 and a second gas supply path connected to the second gas supplier 44 may be provided in the gas injection part 30. The first gas supply path and the second gas supply path may be provided to be independently separated from each other so that the gas supplied from the first gas supplier 42 and a gas supplied from the second gas supplier 44 are separated from each other without being mixed with each other within the gas injection part 30 and then supplied onto the substrate S.

The gas injection part 30 may include an upper frame 32 and a lower frame 34. Here, the upper frame 32 is detachably coupled to the bottom surface of the lid 14, and simultaneously, a portion of a top surface of the upper frame 310, for example, a central portion of the top surface of the upper frame 310 is spaced a predetermined distance from the bottom surface of the lid 14. Thus, the gas supplied from the first gas supplier 42 may be diffused into a space between the top surface of the upper frame 32 and the bottom surface of the lid 14. Also, the lower frame 34 is installed to be spaced a predetermined distance from the bottom surface of the upper frame 32. Thus, the gas supplied from the second gas supplier 44 may be diffused into a space between the top surface of the lower frame 34 and the bottom surface of the upper frame 32. The upper frame 32 and the lower frame 34 may be connected to each other along an outer circumferential surface to define the spaced space therein and be integrated with each other and may have a structure that seals the outer circumferential surface by a separate sealing member.

In the first gas supply path, the gas supplied from the first gas supply part 50 may be diffused into a space between the bottom surface of the lid 14 and the upper frame 32 to pass through the upper frame 32 and the lower frame 34 and then be supplied into the chamber 10. In addition, in the second gas supply path, the gas supplied from the second gas supplier 44 may be diffused in a space between the bottom surface of the upper frame 32 and the top surface of the lower frame 34 to pass through the lower frame 34 and then be supplied into the chamber 10. The first gas supply path and the second gas supply path may not be in communication with each other, and thus, the gas supplied from the first gas supplier 42 and the gas supplied from the second gas supplier 44 may be separately supplied into the chamber 10 via the gas injection part 30.

A first electrode 38 may be installed on the bottom surface of the lower frame 34, and the second electrode 36 may be installed to spaced downward from the lower frame 34 and outward from the first electrode 38 by a predetermined distance. In this case, the lower frame 34 and the second electrode 36 may be disposed to be connected along an outer circumferential surface and may have a structure in which the outer circumferential surface is sealed by a separate sealing member.

As described above, when the first electrode 38 and the second electrode 36 are installed, the gas supplied from the first gas supplier 42 may be injected onto the substrate by passing through the first electrode 38, and the gas supplied from the second gas supplier 44 may be injected onto the substrate through a spaced space between the first electrode 38 and the second electrode 36.

RF power may be applied from the RF power source 50 to any one of the lower frame 34 and the second electrode 36. For example, the lower frame 34 may be grounded, and the RF power may be applied to the second electrode 36 from the RF power source 50. When the lower frame 34 is grounded, the first electrode 38 installed on the bottom surface of the lower frame 34 is also grounded. Thus, when the RF power is applied to the second electrode 36, a first activation region, i.e., a first plasma region, may be defined between the gas injection part 30 and the substrate support part 20, and a second activation region, i.e., a second plasma region may be defined between the first electrode 38 and the second electrode 36.

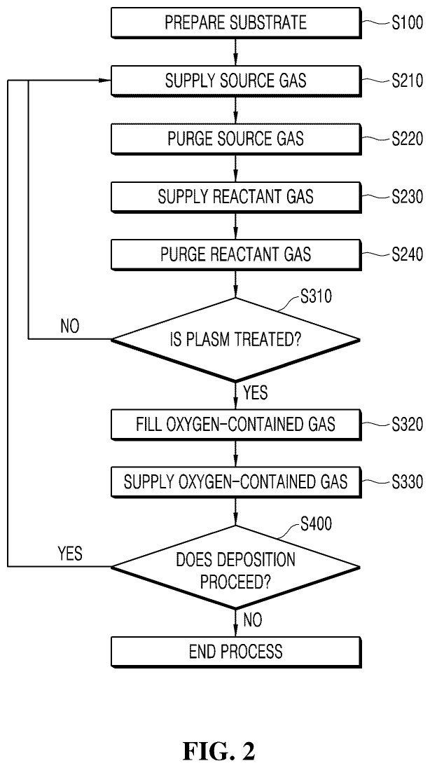

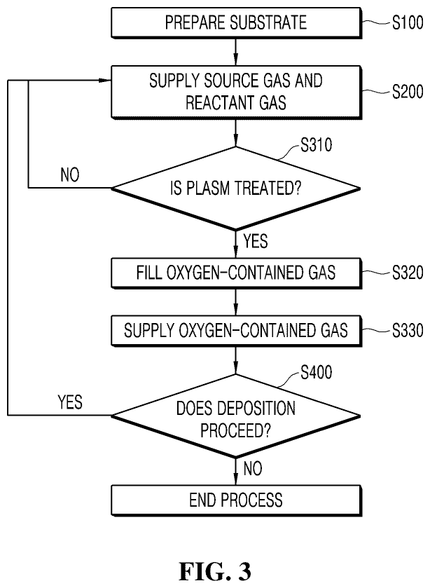

Hereinafter, a method for depositing a thin film in accordance with an exemplary embodiment will be described in detail with reference to FIGS. 2 and 3. The method for forming a silicon insulating layer according to an exemplary embodiment may be performed by the above-described apparatus for processing the substrate, and thus, descriptions that are duplicated with the above-described contents in relation to the apparatus for processing the substrate will be omitted.

FIG. 2 is a schematic view illustrating a method for depositing a thin film in accordance with an exemplary embodiment.

Referring to FIG. 2, a method for forming a silicon insulating layer according to an exemplary embodiment may be a method for forming an oxygen-doped silicon insulating layer and may include a process (S100) of preparing a substrate in a reaction space, a process (S200) of forming a silicon insulating layer on the substrate through an atomic layer deposition process, and a process (S300) of generating plasma in the reaction space by using a gas containing oxygen to dope oxygen into the silicon insulating layer. Here, at least one of the process (S200) of forming the silicon insulating layer and the process (S300) of generating the plasma in the reaction space by using the gas containing oxygen may be performed multiple times.

In the process (S100) of preparing the substrate, the substrate may be prepared in the reaction space of a chamber 10. In the process (S100) of preparing the substrate, the substrate may be loaded into the reaction space of the chamber 10, and the loaded substrate may be seated on a substrate support part 20. As described above, the substrate may include a silicon wafer or glass and also may include a substrate on which a separate thin film is already formed on the silicon wafer or glass. Here, the substrate support part 20 may include an electrostatic chuck to adsorb and maintain the substrate S by using electrostatic force so that the substrate S is seated and supported. Alternatively, the substrate support part 20 may support the substrate S through vacuum adsorption or mechanical force.

In the process (S200) of forming the silicon insulating layer, the silicon insulating layer may be formed on the substrate provided in the reaction space of the chamber 10. Here, the silicon insulating layer may be doped with oxygen through a plasma treatment process to be described later and used as a dielectric for a semiconductor element. For example, the silicon insulating layer may include an interlayer dielectric (ILD), such as a spacer for a gate electrode in a thin film transistor (TFT).

In an exemplary embodiment, the process (S300) of forming the semiconductor layer may be performed in a low temperature process that is performed at a temperature of 600° C. or less. For example, in the process (S200) of forming the silicon insulating layer, a temperature of the substrate may be controlled to a temperature of 100° C. or more and 400° C. or less, or the reaction space of the chamber 10 may be controlled to a temperature of 100° C. or more and 400° C. or less. The silicon insulating layer may be formed in the low temperature process of 100° C. to 400° C. by an atomic layer deposition (ALD) process that performs multiple deposition process cycles in which the source gas and the reactant gas are sequentially supplied, and this will be explained in more detail below.

In the process (S210) of supplying the source gas, the source gas containing silicon (Si) is supplied to the substrate. Here, in the process (S210) of supplying the source gas, the source gas containing silicon (Si) may be supplied onto the substrate through a first gas supply path of the above-described apparatus for processing the substrate. Here, the source gas containing silicon (Si) may include silane, disilane, trisilane, and a gas in which any silane of the silanes is replaced with an amine. For example, the source gas may include trisilylamine (TSA). In the process (S210) of supplying the source gas, the source gas containing silicon (Si) is injected and adsorbed onto the substrate. Here, the process (S210) of supplying the source gas may be performed without applying an RF power.

After the process (S210) of supplying the source gas, a process (S220) of purging the source gas may be performed. In the process (S220) of purging the source gas, the source gas remaining in the reaction space of the chamber 10 may be removed. As described above, in the process (S220) of purging the source gas, an inert gas, for example, an argon (Ar) gas may be supplied to the reaction space, and the argon (Ar) gas may be supplied through at least one of a first gas supply path or a second gas supply path. At this time, the RF power may not be applied while purging the source gas.

After the process (S220) of purging the source gas, a process (S230) of supplying a reactant gas is performed. In the process (S230) of supplying the reactant gas, a reactant gas containing nitrogen is supplied to the substrate. That is, in the process (S230) of supplying the reactant gas, the reactant gas containing nitrogen (N) may be supplied onto the substrate. Here, in the process (S230) of supplying the reactant gas, the reactant gas containing nitrogen may be supplied onto the substrate through the second gas supply path of the above-described apparatus for processing the substrate. Here, the reactant gas containing nitrogen may include an ammonia (NH₃) gas or a nitrous oxide (N₂O) gas. When the reactant gas is supplied to the substrate on which a raw material is adsorbed, the raw material reacts with a reaction material contained in the reactant gas.

Here, the process (S230) of supplying the reactant gas may be performed without applying the RF power. However, the present disclosure is not limited thereto, and in the process (S230) of supplying the reactant gas, to effectively react the reactant with the raw material, the RF power may be applied to the reaction space to activate the reactant gas, thereby generating plasma. As described above, in the process (S230) of supplying the reactant gas, the nitrogen-contained gas supplied by activating the reactant gas may be activated with nitrogen radicals to react and may form the silicon insulating layer on the substrate at a lower process temperature.

After the process (S230) of supplying the reactant gas, the process (S240) of purging the reactant gas may be performed. In the process (S240) of purging the reactant gas, the reactant gas remaining in the reaction space of the chamber 10 may be removed. As described above, like the process (S220) of purging the source gas, in the process (S240) of purging the reactant gas, an inert gas, for example, an argon (Ar) gas may be supplied to the reaction space, and the argon (Ar) gas may be supplied through at least one of the first gas supply path or the second gas supply path.

The method of forming the silicon insulating layer in accordance with an exemplary embodiment may include a process (S300) of generating plasma by using an oxygen-contained gas in the reaction space to dope oxygen into the silicon insulating layer and adjust a hydrogen content of the silicon insulating layer.

That is, in the process (S200) of forming the silicon insulating layer, a deposition process cycle including the process (S210) of supplying the source gas, the process (S220) of purging the source gas, the process (S230) of supplying the reactant gas, and the process (S240) of purging the reactant gas may be performed to form the silicon insulating layer. Here, in the method for forming the silicon insulating layer in accordance with an exemplary embodiment, before the silicon insulating layer having a desired thickness is formed, the process (S300) of generating plasma to dope oxygen into the silicon insulating layer and adjust the hydrogen content of the silicon insulating layer is performed. Here, the process (S300) of generating plasma may be performed selectively. That is, in the process (S300) of generating plasma, whether to perform a plasma treatment process after performing the deposition process cycle at least one time may be selected, and when selecting to perform the plasma treatment process, the plasma treatment process may be performed while forming the silicon insulating layer having the desired thickness. For this, the process (S300) of generating plasma may include, after the deposition process cycle is performed at least one time, a process (S310) of selecting whether to perform the plasma treatment process and a process (S330) of supplying the oxygen-contained gas into the reaction space when the plasma treatment process is selected.

The process (S310) of selecting whether to perform the plasma treatment process may be performed after the deposition process cycle is performed at least one time. That is, the process (S310) of selecting whether to perform the plasma treatment process may be performed after the deposition process cycle including the process (S210) of supplying the source gas, the process (S220) of purging the source gas, the process (S230) of supplying the reactant gas, and the process (S240) of purging the reactant gas is performed at least one time or two or more times. Whether or not to perform the plasma treatment process may be selected by a user, and for this, the apparatus for processing the substrate may include a user interface (UI) such as a human machine interface (HMI) for receiving information from the user regarding whether to perform the plasma treatment process.

If that the plasma treatment process is not performed is selected, an additional deposition process cycle may be performed following the process (S310) of selecting whether to perform the plasma treatment process. That is, if that the plasma treatment process is not performed is selected in the process (S310) of selecting whether to perform the plasma treatment process after the process (S240) of purging the reactant gas during the deposition process cycle, a process (S210) of supplying the source gas in the next deposition process cycle may be performed.

On the other hand, when that the plasma treatment process is performed is selected, that is, when the performing of the plasma treatment process is selected, a process (S330) of supplying the gas containing oxygen to the reaction space is performed. Here, the method for forming the silicon insulating layer in accordance with an exemplary embodiment may include, before the process (S330) of supplying the gas containing oxygen to the reaction space, a process (S320) of filling a storage space for storing the gas containing oxygen with the oxygen-contained gas. Here, the process (S320) of filling the storage space with the gas containing oxygen may include a process of blocking the storage space for storing the oxygen-contained gas, that is, a reservoir from the reaction space and a process of filling the storage space with the oxygen-contained gas.

As will be described later, the plasma treatment process may be a process of supplying the gas containing oxygen to the substrate on which the silicon insulating layer is formed to dope oxygen into the silicon insulating layer and simultaneously remove hydrogen contained in the silicon insulating layer. To efficiently perform the plasma treatment process, it may be necessary to supply a gas having a uniform flow rate per unit time. That is, the oxygen-contained gas may need to be uniformly supplied from a start section of the plasma treatment process, in which the supply of the oxygen-contained gas starts, to an end section of the plasma treatment process, in which the supply of the oxygen-contained gas is ended.

For this, in the process of blocking the storage space for storing the oxygen-contained gas from the reaction space, the reservoir and the reaction space may be blocked by closing a valve (not shown) installed in a supply line for the oxygen-contained gas, which is connected to the reservoir. Here, the supply line for the oxygen-contained gas may mean at least a portion of the path for supplying the oxygen-contained gas to the gas injection part 30. For example, when the oxygen-contained gas is supplied to the gas injection part 30 through the second gas supplier 44, the supply line for the oxygen-contained gas may be at least a portion of the second gas supplier 44. Thus, in the process of blocking the storage space for storing the oxygen-contained gas from the reaction space, a valve (not shown) installed in the second gas supplier 44 to control the supply of the oxygen-contained gas may be closed to block the storage space.

In the process of filling the storage space with the oxygen-contained gas, the oxygen-contained gas maybe continuously supplied to the reservoir while the supply line for the oxygen-contained gas is closed. In this case, the reservoir may be filled with the gas containing oxygen. Thus, if the valve is opened at once to allow the storage space and the reaction space to communicate with each other, the oxygen-contained gas may be uniformly supplied from the start section of the plasma treatment process in which the oxygen-contained gas starts to be supplied.

In the process (S320) of filling the storage space for storing the oxygen-contained gas with the oxygen-contained gas, an inert gas, for example, an argon (Ar) gas may be continuously supplied to the reaction space. For example, when the second gas supplier 44 forms the supply line for the gas containing oxygen, the inert gas may be supplied to the reaction space through the first gas supplier 42. As described above, in the process (S320) of filling the storage space for storing the oxygen-contained gas with the oxygen-contained gas, the inert gas may be supplied to the reaction space through the first gas supplier 42 to purge out by-products and residual gas, which are generated in the previous deposition process cycle, thereby removing the by-products and residual gas from the reaction space and thus preventing unnecessary reaction of oxygen-contained gas.

In the process (S330) of supplying the oxygen-contained gas to the reaction space, the valve installed in the oxygen-contained gas supply line may be opened to allow the storage space storing the oxygen-contained gas to communicate with the reaction space. Here, in the process (S330) of supplying the oxygen-contained gas, the valve installed in the oxygen-contained gas supply line may be opened maximally at once to maximally open the oxygen-contained gas supply line at once. Here, the gas containing oxygen may be at least one of nitrous oxide (N₂O), ozone (O₃), water (H₂O), and oxygen (O₂). In addition, the oxygen-contained gas may be supplied together with at least one gas selected from ammonia (NH₃), nitrogen (N₂), and argon (Ar). That is, the gas supplied to the reaction space may be a gas in which one or more of nitrous oxide (N₂O), ozone (O₃), water (H₂O), ammonia (NH₃), nitrogen (N₂), oxygen (O₂), and argon (Ar) are combined. For example, when supplying the nitrous oxide (N₂O) gas to the reaction space, nitrous oxide (N₂O) may react with molecules (Si—H) in which silicon and hydrogen contained in the silicon insulating layer are bonded as shown in a reaction formula below, and in some case, may be doped with oxygen in the silicon insulating layer through substitution reaction with molecules (N—H) in which nitrogen and hydrogen are bonded. In addition, as a result, hydrogen contained in the silicon insulating layer may be removed in a unit of an atomic layer.

### [Reaction Formula]

$${NH}_{x} + {SiH}_{x} + {N}_{2} O \to {Si}_{x} {O}_{y} {N}_{z} + OH$$

Here, the process (S330) of supplying the gas containing oxygen to the reaction space may include a process of generating plasma by using the gas containing oxygen in the reaction space. That is, in the process (S330) of supplying the gas containing oxygen to the reaction space, RF power may be applied to the reaction space to activate the gas containing oxygen, thereby generating plasma so that the molecules (N—H molecules) in which nitrogen and hydrogen are bonded and the molecules (Si—H) in which silicon and hydrogen are bonded effectively react with the gas containing oxygen. As described above, in the process (S330) of supplying the oxygen-contained gas, the oxygen-contained gas in the reaction space may be activated to generate the plasma of the oxygen-contained gas, thereby removing hydrogen contained in the silicon insulating layer at a low temperature and doping oxygen. For example, when the nitrous oxide (N₂O) gas is activated and supplied to the substrate, hydrogen contained in the silicon insulating layer may be effectively removed at a low temperatures of 100° C. or more and 400° C. or less.

After the process (S330) of supplying the gas containing oxygen to the reaction space, a process (S400) of selecting whether to perform a deposition process may be performed. If that the deposition process is ended is selected in the process (S400) of selecting whether to perform the deposition process, the process of forming the silicon insulating layer, which includes the process (S200) of forming the silicon insulating layer and the process (S300) of generating the plasma is ended. On the other hand, if that the deposition process is continuously performed is selected in the process (S400) of selecting whether to perform the deposition process, the process (S200) of forming the silicon insulating layer is performed. That is, if that the deposition process is continuously performed is selected in the process (S400) of selecting whether to perform the deposition process, the process (S210) of supplying the source gas for the next deposition process cycle may be performed. In addition, although not shown, in the process (S400) of selecting whether to perform the deposition process, it is possible to select to additionally perform the process of generating the plasma, that is, the plasma treatment. As described above, the selection of such processes can also be performed by the user through the user interface.

If that the deposition process is continuously performed is selected in the process (S400) of selecting whether to perform the deposition process, a process of filling the storage space for the source gas with the source gas may be performed. Here, the process of filling the storage space with the source gas may include a process of blocking the storage space for storing the source gas from the reaction space and a process of filling the storage space for storing the source gas with the source gas. Here, the process of filling the source gas with the source gas may have the same principle as the process (S320) of filling the storage space with the oxygen-contained gas, and thus, duplicated descriptions will be omitted. As described above, when the source gas is supplied to the reaction space at once in the process (S210) of supplying the source gas after performing the plasma treatment process, the source gas may be uniformly supplied from the start section of the deposition process in which the source gas starts to be supplied.

Here, in the process of filling the storage space for storing the source gas with the source gas, the inert gas, for example, the argon (Ar) gas may be continuously supplied to the reaction space. That is, when the first gas supplier 42 forms the source gas supply line, the inert gas may be supplied to the reaction space through the second gas supplier 44. As described above, in the process of filling the source gas supply line with the source gas, the inert gas may be supplied to the reaction gas through the second gas supplier 44 to purge out by-products and residual gas, which are generated in the previous treatment process, thereby removing the by-products and residual gas from the reaction space and thus preventing unnecessary reaction of the source gas.

As described above, in accordance with the exemplary embodiment, the silicon insulating layer may be exposed to the plasma generated by using the gas containing the oxygen to perform the plasma treatment, thereby doping the oxygen on the silicon insulating layer and removing the hydrogen contained in the silicon insulating layer in the unit of the atomic layer.

In addition, in the method for forming the silicon insulating layer in accordance with an exemplary embodiment, during the deposition process cycle for depositing the silicon insulating layer at the desired thickness, a plasma treatment process cycle for doping oxygen into the silicon insulating layer and removing hydrogen of the silicon insulating layer may be selectively performed. Here, in general, as the number of plasma process cycles performed on the silicon insulating layer increases, a doped oxygen concentration may increases, and a hydrogen content may decrease. However, if the number of plasma treatment cycles to be performed excessively increases, the components of the silicon insulating layer may be changed undesirably. In other words, as described above, hydrogen may be removed from the silicon insulating layer through a substitution reaction with nitrous oxide (N₂O) contained in the plasma gas. If the number of plasma process cycles excessively increases, the oxygen content in the silicon insulating layer may excessively increase. Thus, in the method for forming the silicon insulating layer in accordance with an exemplary embodiment, the treatment process may be effectively performed after performing the deposition process cycle at least one time to effectively remove the hydrogen content within the silicon insulating layer that is doped with oxygen, and also, the components of the silicon insulating layer, which are changed in accordance with the plasma treatment may be effectively controlled.

FIG. 3 is a schematic view illustrating a method for forming a silicon insulating layer in accordance with another exemplary embodiment.

Referring to FIG. 3, a method for forming a silicon insulating layer according to another exemplary embodiment may be a method for forming an oxygen-doped silicon insulating layer and may include a process (S100) of preparing a substrate in a reaction space, a process (S200) of supplying a gas containing silicon and a gas containing nitrogen onto the substrate to form a silicon insulating layer through an atomic layer deposition process, and a process (S300) of generating plasma in the reaction space by using a gas containing oxygen. Here, at least one of the process (S200) of forming the silicon insulating layer and the process (S300) of generating the plasma in the reaction space by using the gas containing oxygen may be performed multiple times.

The method for forming the silicon insulating layer according to another embodiment of the present invention may be different from the method in accordance with the above-described embodiment only in the process (S200) of forming a silicon insulating layer, and thus, the process (S100) of providing a substrate in the reaction space and the process (S300) generating plasma may be applied as they are. Thus, duplicated descriptions of the process (S100) of preparing the substrate and the process (S300) of generating plasma in another exemplary embodiments will be omitted.

Here, the process (S200) of forming the silicon insulating layer may be performed by a chemical vapor deposition (CVD) process that simultaneously supplies a source gas and a reactant gas. In this case, the source gas may be a gas containing silicon and may include silane, disilane, trisilane, and a gas in which any silane of the silanes is replaced with an amine. For example, the source gas may include trisilylamine (TSA). In addition, the reactant gas may be a nitrogen-contained gas and may include an ammonia (NH₃) gas or a nitrous oxide (N₂O) gas. In another exemplary embodiment, the process (S200) of forming the silicon insulating layer may be performed through a chemical vapor deposition process in which the source gas and the reactant gas are simultaneously supplied.

Here, the process (S200) of forming the silicon insulating layer may be performed without applying RF power. However, the present disclosure is not limited thereto, and in the process (S200) of forming the silicon insulating layer, to effectively react the reactant with the raw material, the RF power may be applied to the reaction space to generate plasma. In addition, the process (S200) of forming the silicon insulating layer may be performed at a low temperature process of 600° C. or less and may be performed by controlling a temperature of the substrate to a temperature of 100° C. or more and 400° C. or less, or controlling the reaction space of the chamber 10 to a temperature of 100° C. or more and 400° C. or less.

After the process (S200) of forming the silicon insulating layer through the chemical vapor deposition process, a process (S300) of generating plasma by using an oxygen-containing gas in the reaction space to dope oxygen into the silicon insulating layer and adjust a hydrogen content of the silicon insulating layer may be performed. Here, after the process (S300) of generating the plasma, the process (S200) of forming the silicon insulating layer may be performed again as in the above-described exemplary embodiment.

In addition, in the process (S300) of generating the plasma, as described above, a gas in which one or more of nitrous oxide (N₂O), ozone (O₃), water (H₂O), ammonia (NH₃), nitrogen (N₂), oxygen (O₂), and argon (Ar) are combined may be supplied to the reaction space, and the process (S300) of generating the plasma may include a process of blocking a storage space for storing the oxygen-containing gas from the reaction space, a process of filling the storage space with the gas containing oxygen, and a process of supplying the gas containing oxygen to the reaction space to allow the storage space to communicate with the reaction space. Here, in the process of supplying the gas containing oxygen, the gas containing oxygen may be supplied by maximally opening a supply line, which connects the storage space to the reaction space, at once. As described above, after the process (S300) of generating the plasma, if that the deposition process is continuously performed is selected in the process (S400) of selecting whether to perform the deposition process, a process of filling a storage space for a source gas and a storage space for a reactant gas with the source gas and the reactant gas may be performed. Here, the process of filling the storage space for the source gas and the storage space for the reactant gas with the source gas and the reactant gas, respectively, may have the same principle as the process (S320) of filling the above-described storage space with the gas containing oxygen, and thus duplicated descriptions will be omitted.

As described above, in accordance with the exemplary embodiment, the silicon insulating layer may be exposed to the plasma generated by using the gas containing the oxygen to perform the plasma treatment, thereby doping the oxygen on the silicon insulating layer and removing the hydrogen contained in the silicon insulating layer in the unit of the atomic layer.

In addition, the plasma treatment may be selectively performed to effectively control the hydrogen content within the oxygen-doped silicon insulating layer and also effectively control the components of the silicon insulating layer, which are changed in accordance with the plasma treatment.

Although the specific embodiments are described and illustrated by using specific terms, the terms are merely examples for clearly explaining the exemplary embodiments, and thus, it is obvious to those skilled in the art that the exemplary embodiments and technical terms can be carried out in other specific forms and changes without changing the technical idea or essential features. Therefore, it should be understood that simple modifications in accordance with the exemplary embodiments of the present invention may belong to the technical spirit of the present invention.

1. A method for forming a silicon insulating layer that is doped with oxygen, the method comprising:
preparing a substrate in a reaction space;
forming a silicon insulating layer on the substrate through an atomic layer deposition process; and
generating plasma in the reaction space by using a gas containing oxygen to dope oxygen into the silicon insulating layer.

2. The method of claim 1, wherein at least one of the forming of the silicon insulating layer or the generating of the plasma is preformed multiple times.

3. The method of claim 1, wherein, after the generating of the plasma, the forming of the silicon insulating layer is performed.

4. The method of claim 1, wherein the generating of the plasma comprises supplying a gas, in which one or more of nitrous oxide (N₂O), ozone (O₃), water (H₂O), ammonia (NH₃), nitrogen (N₂), oxygen (O₂), and argon (Ar) are combined, into the reaction space.

5. The method of claim 1, wherein the forming of the silicon insulating layer comprises:
supplying a source gas containing trisilylamine (TSA); and
supplying a reactant gas containing nitrogen.

6. The method of claim 1, wherein the generating of the plasma comprises:
blocking a storage space for storing the gas containing oxygen from the reaction space;
filling the storage space with the gas containing oxygen; and
allowing the storage space to communicate with the reaction space so as to supply the gas containing oxygen to the reaction space.

7. The method of claim 6, wherein, in the supplying of the gas containing oxygen, a supply line that connects the storage space to the reaction space is maximally opened at once to supply the gas containing oxygen.

8. The method of claim 1, wherein the substrate or the reaction space is maintained at a temperature of 100° C. to 400° C.

9. A method for forming a silicon insulating layer that is doped with oxygen, the method comprising:
preparing a substrate in a reaction space;
supplying a gas containing silicon and a gas containing nitrogen onto the substrate to form a silicon insulating layer on the substrate through an atomic layer deposition process; and
generating plasma in the reaction space by using a gas containing oxygen to dope oxygen into the silicon insulating layer.

10. The method of claim 9, wherein at least one of the forming of the silicon insulating layer or the generating of the plasma is preformed multiple times.

11. The method of claim 9, wherein, after the generating of the plasma, the forming of the silicon insulating layer is performed.

12. The method of claim 9, wherein the generating of the plasma comprises supplying a gas, in which one or more of nitrous oxide (N₂O), ozone (O₃), water (H₂O), ammonia (NH₃), nitrogen (N₂), oxygen (O₂), and argon (Ar) are combined, into the reaction space.

13. The method of claim 9, wherein the gas containing silicon comprises trisilylamine (TSA).

14. The method of claim 9, wherein the generating of the plasma comprises:
blocking a storage space for storing the gas containing oxygen from the reaction space;
filling the storage space with the gas containing oxygen; and
allowing the storage space to communicate with the reaction space so as to supply the gas containing oxygen to the reaction space.

15. The method of claim 14, wherein, in the supplying of the gas containing oxygen, a supply line that connects the storage space to the reaction space is maximally opened at once to supply the gas containing oxygen.

16. The method of claim 9, wherein the substrate or the reaction space is maintained at a temperature of 100° C. to 400° C.
